(19) United States
(12) Patent Application Publication
(10) Pub. No.: US 2006/0279201 A1
(43) Pub. Date: Dec. 14, 2006

(54) DROPLET DISCHARGE METHOD, ELECTRO OPTICAL DEVICE AND ELECTRONIC APPARATUS

(75) Inventors: Nobuaki NAGAE, Tino (JP); Kazumi ARUGA, Fujimi (JP)

Correspondence Address: HARNESS, DICKEY & PIERCE, P.L.C., P.O. BOX 828, BLOOMFIELD HILLS, MI, 48303, US

(73) Assignee: SEIKO EPSON CORPORATION, Tokyo (JP)

(21) Appl. No.: 11/423,238

(22) Filed: Jun. 9, 2006

(30) Foreign Application Priority Data
Jun. 10, 2005 (JP) 2005-170462

(51) Int. Cl. H05B 33/00; H01L 51/50

(52) U.S. Cl. 313/503

(57) ABSTRACT

A droplet discharge method includes discharging a droplet of a functional liquid on a discharged material receiver provided on a substrate from a plurality of nozzles in a plurality of discharge heads while the plurality of discharge heads relatively scan the substrate. The size of a discharge area formed of the plurality of nozzles in a first direction perpendicular to a second direction in which the plurality of discharge heads relatively scan the substrate is larger than the size of the discharged material receiver in the first direction. If the whole of the discharged material receiver is covered by the discharge area, a droplet of the functional liquid is discharged from the plurality of nozzles to the discharged material receiver, and if at least part of the discharged material receiver is not covered by the discharge area, a droplet of the functional liquid is not discharged from the plurality of nozzles to the discharged material receiver.

### BACKGROUND

1. Technical Field

The present invention relates to a droplet discharge method, an electro optical device and an electronic apparatus.

2. Related Art

Droplet discharge heads in ink jet printers can discharge minute ink droplets in a dot form, and offers extremely high accuracy in terms of evenness of the size and pitch of ink droplets. This technique is applied to fields of fabrication of various products. For example, this technique can also be applied to the formation of a color filter in a liquid crystal device, a luminescent part in an organic electro luminescence (EL) display, and so on. Specifically, a functional liquid such as a special ink or photosensitive resin liquid is loaded in a droplet discharge head, and droplets of the functional liquid are discharged onto a substrate of an electro optical device (refer to e.g. JP-A-2004-267927). In the color filter or luminescent part formed in such a method, layers of plural kinds of colors are frequently formed. Therefore, plural kinds of functional liquids are discharged on a substrate by using plural apparatuses different for each one kind.

The film-form color filter layer or luminescent part formed by the above-described method often involves plural kinds of colors. In the apparatus described in the aforementioned JP-A-2004-267927, plural kinds of functional liquids are discharged on a substrate by using plural apparatus different for each one kind, which leads to long discharge time. For simultaneous discharging of all kinds of liquid materials in one scanning with use of one apparatus in order to shorten discharge time, it is possible to use a method in which heads with nozzles for discharging the respective kinds of liquid materials are arranged in the scanning direction so that the nozzles are aligned with each other, and the liquid materials are simultaneously discharged from the respective heads in one scanning, for example.

However, in discharging of a liquid material from a head, a trouble is frequently caused in which streak unevenness arises in the liquid material discharged from nozzles at the both ends of the head. Accordingly, if the both ends of the arranged heads are on the same rows parallel to the scanning direction, the positions of the streak unevenness of liquid materials discharged from the heads overlap with each other, which problematically emphasize the existence of the streak unevenness of liquid materials across the entire substrate.

### SUMMARY

An advantage of some aspects of the invention is to provide a droplet discharge method, an electro optical device and an electronic apparatus that each can prevent the occurrence of recognizable unevenness of a discharged functional liquid across the whole of a substrate.

A droplet discharge method according to an aspect of the invention includes discharging a droplet of a functional liquid on a discharged material receiver provided on a substrate from a plurality of nozzles in a plurality of discharge heads while the plurality of discharge heads relatively scan the substrate. In the method, the size of a discharge area formed of the plurality of nozzles in a first direction perpendicular to a second direction in which the plurality of discharge heads relatively scan the substrate is larger than the size of the discharged material receiver in the first direction. If the whole of the discharged material receiver is covered by the discharge area, a droplet of the functional liquid is discharged from the plurality of nozzles to the discharged material receiver, and if at least part of the discharged material receiver is not covered by the discharge area, a droplet of the functional liquid is not discharged from the plurality of nozzles to the discharged material receiver.

In related arts, a situation possibly arises where, in one scanning, the whole of some discharged material receivers is covered by a discharge area formed of nozzles in a discharge head, while only part of other discharged material receivers is covered by a discharge area formed of nozzles in a discharge head. Therefore, it is needed to repeat the discharging of the liquid material in association with the scanning of the discharge head, with the discharge head itself being moved in the direction perpendicular to the scanning direction before each discharging. However, in such discharging operation, the functional liquid is discharged in one discharged material receiver twice or more with time intervals, which possibly causes unevenness in the discharged functional liquid.

According to the aspect of the invention, when the entire discharged material receiver is covered by a discharge area of the nozzles, droplets of a functional liquid are discharged from the nozzles to the discharged material receiver. In contrast, when only part of a discharged material receiver is covered by a discharge area, or a discharged material receiver is not covered by a discharge area at all, the functional liquid is not discharged. Therefore, there is no possibility of occurrence of unevenness in discharged material receivers. Thus, unevenness of the functional liquid can be made obscure across the entire substrate.

In the droplet discharge method, it is preferable that in the discharging, the plurality of discharge heads relatively scan the substrate in a state where the positions in the first direction of nozzles at both ends in the first direction of the plurality of nozzles in the plurality of discharge heads are offset relative to each other on each discharge head basis.

According to this feature, the positions that readily cause streak unevenness in the respective heads, i.e., the positions of the nozzles provided at the both ends of the discharge heads are offset relative to each other on each discharge head basis. Therefore, when the functional liquid is discharged while a head unit according to one embodiment of the invention scans the substrate, the positions of streak unevenness in the functional liquid discharged from the respective discharge heads do not overlap with each other.

An electro optical device according to another aspect of the invention includes a substrate on which a functional liquid is discharged by the above-described droplet discharge method.

According to this aspect, droplets of a functional liquid are discharged by a droplet discharge method that allows reduction of unevenness of the functional liquid across a substrate. Therefore, a high-quality electro optical device allowing uniform displaying can be achieved.

An electronic apparatus according to still another aspect of the invention includes the above-described electro optical device.

According to this aspect, the high-quality electro optical device allowing uniform displaying is incorporated. Therefore, an electronic apparatus having an excellent display performance can be achieved.

### BRIEF DESCRIPTION OF THE DRAWINGS

The invention will be described with reference to the accompanying drawings, wherein like numbers reference like elements.

FIG. 1 is a perspective view illustrating the configuration of a liquid crystal device according to an embodiment of the invention.

FIGS. 2A and 2B are plan views illustrating the structure of a color filter substrate according to the embodiment.

FIG. 3 is a perspective view illustrating the entire structure of a droplet discharge device according to the embodiment.

FIG. 4 is a plan view illustrating the structure of a carriage in the droplet discharge device according to the embodiment.

FIG. 5 is a plan view illustrating the external structure of a head in the droplet discharge device according to the embodiment.

FIG. 6 is a diagram illustrating an arrangement of heads in the droplet discharge device according to the embodiment.

FIGS. 7A and 7B are diagrams illustrating the internal structure of a head in the droplet discharge device according to the embodiment.

FIG. 8 is a block diagram showing the configuration of a controller in the droplet discharge device according to the embodiment.

FIG. 9A is a diagram illustrating the configuration of a head drive unit in the droplet discharge device according to the embodiment.

FIG. 9B is a diagram illustrating a drive signal supplied from the head drive unit.

FIG. 10 is a first diagram illustrating a droplet discharge method according to the embodiment.

FIG. 11 is a second diagram illustrating the droplet discharge method according to the embodiment.

FIG. 12 is a third diagram illustrating the droplet discharge method according to the embodiment.

FIG. 13 is a perspective view illustrating the configuration of an electronic apparatus to which the embodiment is applied.

### DESCRIPTION OF EXEMPLARY EMBODIMENTS

Embodiments of the invention will be described below with reference to the drawings. In the drawings, scaling is adequately changed for each member so that each member has a recognizable size in the drawings.

Electro Optical Device

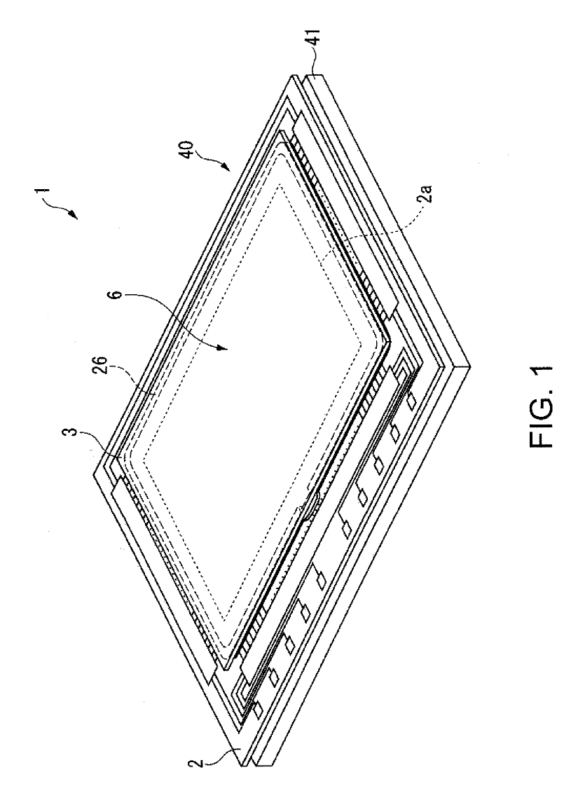

FIG. 1 is a perspective view illustrating the configuration of a liquid crystal device 1 according to an embodiment of the invention.

Referring to FIG. 1, the liquid crystal device 1 is formed mainly of a liquid crystal panel 40 and a backlight 41. The liquid crystal panel 40 has a configuration in which an active matrix substrate 2 and a color filter substrate 3 are applied to each other via the intermediary of a sealing material 26 therebetween, and a liquid crystal 6 is interposed among the active matrix substrate 2, the color filter substrate 3 and the sealing material 26. A display region 2a indicated by the dashed line in FIG. 1 is a region on which pictures, moving images and so on are displayed.

The present embodiment adopts as the liquid crystal device 1 an active-matrix liquid crystal device that employs as its switching elements thin-film diode (TFD) elements, which are a two-terminal nonlinear element. However, it should be obvious that the liquid crystal device 1 may be a liquid crystal device employing thin-film transistor (TFT) elements as its switching elements, or a passive-matrix liquid crystal device, for example. The liquid crystal panel 40 is formed by applying two large-size mother substrates to each other and then cutting the applied mother substrates. That is, multiple panels are obtained from one pair of mother substrates. One of the two mother substrates is a color-filter mother substrate for producing the color filter substrates 3, and the other is an active-matrix mother substrate for producing the active matrix substrates 2.

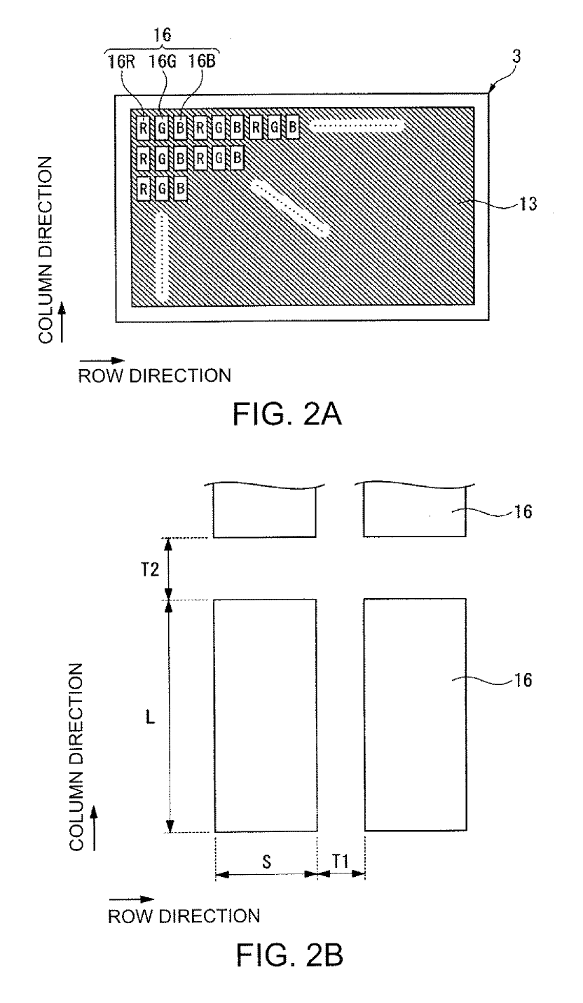

FIGS. 2A and 2B are plan views illustrating the structure of the color filter substrate 3. FIG. 2A is a diagram showing the entire structure of the color filter substrate 3. FIG. 2B is a diagram showing part of the color filter substrate 3 in a magnified form.

Referring to FIG. 2A, the color filter substrate 3 is a rectangular substrate composed of a transparent material such as glass or plastic. A light-blocking layer 13 is provided on the color filter substrate 3. Color filters 16 including red layers 16R, green layers 16G and blue layers 16B are provided corresponding to the region (pixels) surrounded by the light-blocking layer 13. In addition, an overcoat layer (not shown) is formed on the color filter substrate 3 to cover the color filters 16, and formed on the overcoat layer is an alignment layer (not shown). The alignment layer is a horizontal alignment layer that is composed of e.g. polyimide and has a rubbing-treated surface.

As shown in FIG. 2B, each of the red layers 16R (the green layers 16G and the blue layers 16B) has a rectangular shape, and the lengths S and L of short and long sides thereof are about 170 μm and about 510 μm. respectively. As for gaps between the neighboring color filters 16, a gap T1 along the row direction has a gap length of about 20 μm, and a gap T2 along the column direction has a gap length of about 40 μm.

Droplet Discharge Device A droplet discharge device (hereinafter, referred to as a discharge device) 100 according to the present embodiment will be described below.

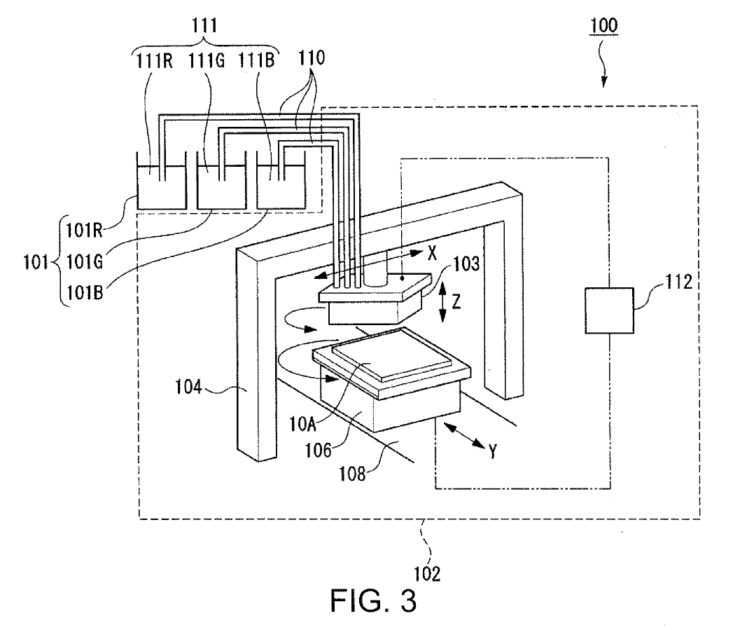

Referring to FIG. 3, the discharge device 100 is composed mainly of tanks 101 that hold liquid materials 111 and a scanning discharge unit 102 that is supplied with the liquid materials 111 from the tanks 101 via tubes 110.

The liquid materials 111 include three kinds of materials for example: a material 111R for forming the red layers 16R of the color filters 16 in the above-described liquid crystal device 1 (hereinafter, referred to as a red material 111R), a material 111G for forming the green layers 16G (hereinafter, referred to as a green material 111G), and a material 111B for forming the blue layers 16B (hereinafter, referred to as a blue material 111B).

The tanks 101 are classified into a red material tank 101R for holding the red material 111R, a green material tank 101G for holding the green material 111G, and a blue material tank 101B for holding the blue material 111B, and thus separately hold the above-described three kinds of the liquid materials. Each tank is provided with e.g. a pressure pump (not shown). The driving of the pressure pump applies a pressure to the inside of the tank 101, which allows the supply of the liquid material 111 from the tank 101 to the scanning discharge unit 102.

Used as the red material 111R is a solution prepared through the following procedure for example: red inorganic pigments such as iron oxide red pigments or cadmium red pigments are dispersed in polyurethane oligomer, and then added thereto are butyl carbitol acetate as a solvent and a nonionic surfactant as a dispersant, followed by adjustment of the viscosity of the resultant solution into a certain viscosity range.

Used as the green material 111G is a solution prepared through the following procedure for example: green inorganic pigments such as chromium oxide green pigments or cobalt green pigments are dispersed in polyurethane oligomer, and then added thereto are cyclohexanone and butyl acetate as a solvent and a nonionic surfactant as a dispersant, followed by adjustment of the viscosity of the resultant solution into a certain viscosity range.

Used as the blue material 111B is a solution prepared through the following procedure for example: blue inorganic pigments such as ultramarine blue pigments or iron blue pigments are dispersed in polyurethane oligomer, and then added thereto are butyl carbitol acetate as a solvent and a nonionic surfactant as a dispersant, followed by adjustment of the viscosity of the resultant solution into a certain viscosity range.

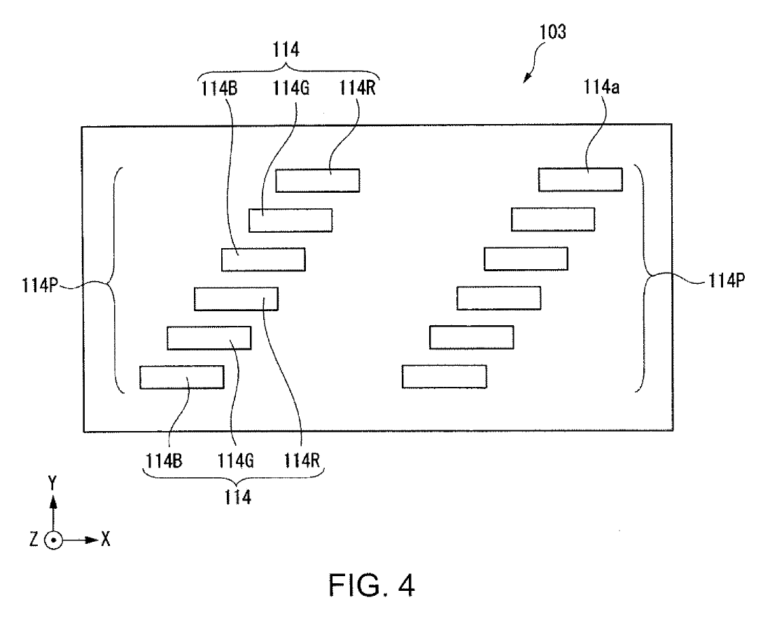

The scanning discharge unit 102 includes a carriage 103 that holds a plurality of heads 114 (see FIG. 4), a carriage position control unit 104 that controls the position of the carriage 103, and a stage 106 that holds thereon a base 10A for forming a color-filter mother substrate. The scanning discharge unit 102 also includes a stage position control unit 108 that controls the position of the stage 106 and a controller 112. An actual discharge device 100 has the plural (e.g., ten) carriages 103. FIG. 3 illustrates only one carriage 103 for simplified description.

The carriage position control unit 104 has a function of moving the carriage 103 in the X-axis direction and the Z-axis direction, and rotating the carriage 103 in the rotation directions about the Z-axis in response to a signal from the controller 112. The stage position control unit 108 has a function of moving the stage 106 in the Y-axis direction, and rotating the stage 106 in the rotation directions about the Z-axis in response to a signal from the controller 112.

In this manner, the carriage 103 moves in the X-axis direction under the control by the carriage position control device 104. In addition, the stage 106 moves in the Y-axis direction under the control by the stage position control device 108. That is, the carriage position control device 104 and the stage position control device 103 change the position of the heads 114 relative to the stage 106.

Specifically, the movement of both or either one of the carriage 103 and the stage 106 allows the carriage 103 to scan the stage 106 (or the base 10A held on the stage 106). The present embodiment employs scanning operation in which the carriage 103 does not move while the stage 106 moves. The following description is based on such scanning operation.

FIG. 4 is a diagram of one carriage 103 when the carriage 103 is viewed from the stage 106. The direction perpendicular to the drawing plane of FIG. 4 is equivalent to the Z-axis direction. The horizontal direction of the drawing plane of FIG. 4 is the X-axis direction, while the vertical direction thereof is the Y-axis direction.

As shown in FIG. 4, the carriage 103 holds a plurality of heads 114 that each have the same structure and size. The heads 114 include three kinds of heads: heads 114R for discharging the red material 111R of the liquid materials 111, heads 114G for discharging the green material 111G, and heads 114B for discharging the blue material 111B.

In the present embodiment, four heads 114R, four heads 114G and four heads 114B are provided in one carriage 103, and therefore the total number of heads 114 in one carriages 103 is twelve. The positional relationship among the heads 114 will be described later. In the present specification, six heads 114 adjacent to one another in the Y-axis direction are sometimes expressed as a head group 114P.

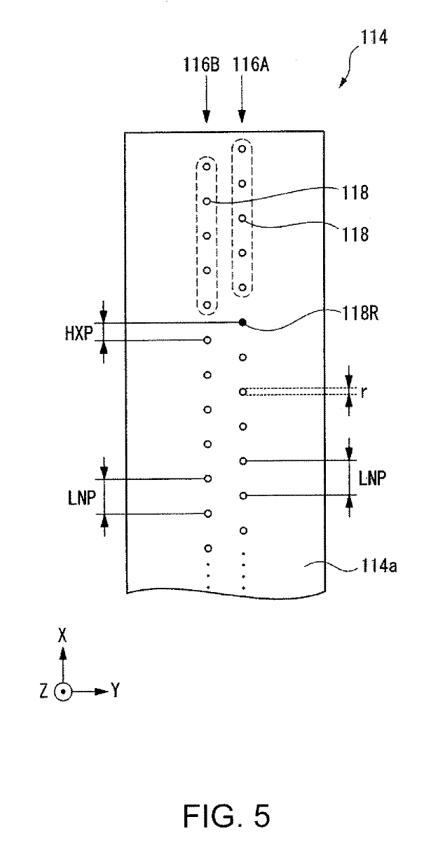

FIG. 5 is a diagram illustrating a bottom face 114a of the head 114. The shape of the bottom face 114a is a rectangle having two opposed long sides and two opposed short sides. The bottom face 114a is opposed to the stage 106 (the normal of the bottom face 114a is parallel to the Z-axis direction in FIG. 5). The direction parallel to the long sides of the head 114 is the X-axis direction in FIG. 5, while the direction parallel to the short sides of the head 114 is the Y-axis direction in FIG. 5.

On the bottom face 114a, nozzles 118 are arranged on two rows (a row 116A and a row 116B) along the X-axis direction. Each of the two rows includes ninety nozzles 118. The nozzle diameter r of each nozzle 118 is about 30 μm. In each of the rows 116A and 116B, the nozzles 118 have a certain pitch LNP of about 140 μm. The positions of the nozzles 118 in the nozzle row 116B are offset relative to those in the nozzle row 116A in the negative X-axis direction (the lower direction in FIG. 5) by the distance half the nozzle pitch LNP (i.e., about 70 μm). Note that the number of nozzle rows provided on the head 114 is not limited to two. The number of rows may be increased to three, four, or a greater natural number, or alternatively may be only one.

Since each of the nozzle rows 116A and 116B includes 90 nozzles, one head 114 is provided with 180 nozzles. However, at each of the both ends of the nozzle row 116A, the five nozzles from the nozzle at the end of the nozzle row (the nozzles surrounded by the dashed line in FIG. 5) are pausing nozzles that do not discharge the liquid material 111. Similarly, at each of the both ends of the nozzle row 116B, the five nozzles from the nozzle at the end of the nozzle row (the nozzles surrounded by the dashed line in FIG. 5) are pausing nozzles that do not discharge the liquid material 111. Therefore, of 180 nozzles 118 in the head 114, nozzles other than 20 nozzles near the both ends of the head 114, i.e., 160 nozzles 118 discharge the liquid material 111 as discharge nozzles.

In the present specification, of 90 nozzles 118 included in the nozzle row 116A, the sixth nozzle from the nozzle at one row end (for example, the sixth nozzle 118 from the upper end nozzle in FIG. 5) is expressed as a reference nozzle 118R, for description of the positional relationship among the heads 114. That is, the uppermost discharge nozzle, in FIG. 5, of 80 discharge nozzles in the nozzle row 116A corresponds to the reference nozzle 118R of the head 114. The position of the reference nozzle 118R is not limited to the above-described position as long as all the heads 114 employ the same way of specifying the reference nozzle 118R therein.

The positional relationship among six heads 114 in the head group 114P will be described below.

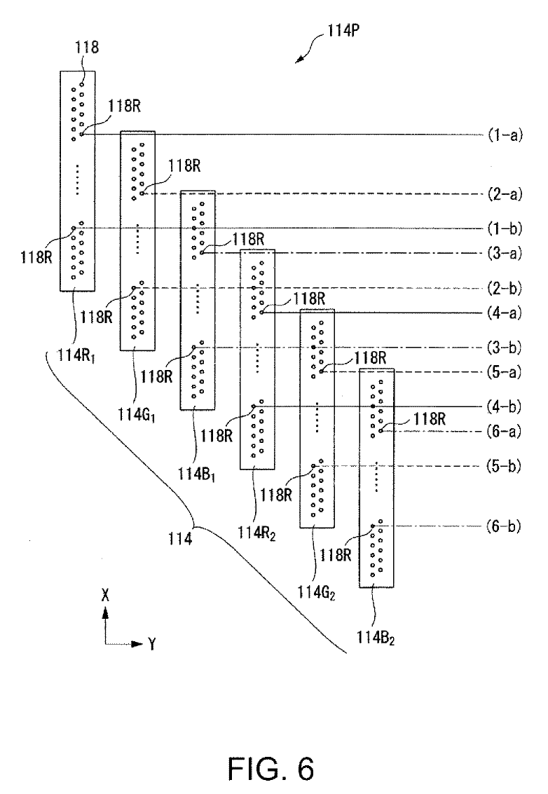

FIG. 6 is a diagram showing the relative positional relationship among the heads 114. In FIG. 6, two groups of the heads 114R, 114G and 114B shown in FIG. 4 are differentiated from each other by expressing them as heads 114R₁, 114G₁ and 114B₁ and heads 114R₁, 114G₂ and 114B₂.

As shown in FIG. 6, the head group 114P is disposed so that the neighboring heads 114 are offset relative to each other in the X-axis direction. The head 114G₁, which is adjacent to the head 114R₂ is provided so as to be offset relative to the head 114R₁ in the negative X-axis direction in FIG. 6, for example. Similarly, the head 114B₁, which is adjacent to the head 114G₁, is provided so as to be offset relative to the head 114G₁ in the negative X-axis direction in FIG. 6, for example. The head 114R₂ adjacent to the head 114B₁, the head 114G₂ adjacent to the head 114R₂, and the head 114B₂ adjacent to the head 114G₂ are also provided so as to be offset relative to the adjacent head 114 in the negative X-axis direction in FIG. 6 similarly.

In FIG. 6, the positions in the X-axis direction of the reference nozzles 118R in the head 114R₁ are 1-a and 1-b (indicated by solid lines). The positions in the X-axis direction of the reference nozzles 118R in the head 114G₁ are 2-a and 2-b (indicated by dashed lines). The positions in the X-axis direction of the reference nozzles 118R in the head 114B₁ are 3-a and 3-b (indicated by chain lines). The positions in the X-axis direction of the reference nozzles 118R in the head 114R₂ are 4-a and 4-b (indicated by solid lines). The positions in the X-axis direction of the reference nozzles 118R in the head 114G₂ are 5-a and 5-b (indicated by dashed lines). The positions in the X-axis direction of the reference nozzles 118R in the head 114B₂ are 6-a and 6-b (indicated by chain lines).

Since the heads 114 having the same structure are offset relative to one another in the X-axis direction, the positions in the X-axis direction (1-a)-(6-b) of the reference nozzles 118R provided in the respective heads 114 are offset relative to each other. As a result, in discharging with the scanning of the carriage 103, streak unevenness of the liquid material 111 discharged from the reference nozzles 118R, which are the end nozzles 118, can be prevented from overlapping with each other.

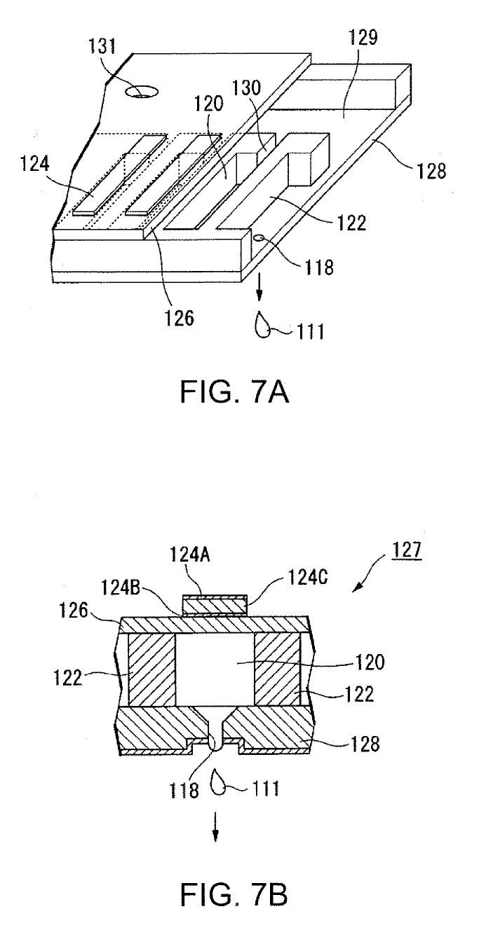

The internal structure of the head 114 will be described below. As shown in FIGS. 7A and 7B, each head 114 is an ink jet head. More specifically, each head 114 includes a diaphragm 126 and a nozzle plate 128. Provided between the diaphragm 126 and the nozzle plate 128 is a liquid reservoir 129 that is always filled with the liquid material 111 supplied from the tank 101 via a hole 131.

A plurality of partition walls 122 are also provided between the diaphragm 126 and the nozzle plate 128. The space defined by the diaphragm 126, the nozzle plate 128 and a pair of partition walls 122 corresponds to a cavity 120. One cavity 120 is provided for each nozzle 118, and therefore the number of the cavities 120 is the same as the number of the nozzles 118. The liquid material 111 is supplied from the liquid reservoir 129 to the cavities 120 via supply ports 130 that are each provided between a pair of partition walls 122.

On the diaphragm 126, oscillators 124 are placed corresponding to the respective cavities 120. The oscillator 124 has a piezo element 124C, and a pair of electrodes 124A and 124B that sandwich the piezo element 124C. Applying a drive voltage between the pair of electrodes 124A and 124B leads to discharging of the liquid material 111 from the corresponding nozzle 118. The shape of the nozzle 118 is adjusted so that liquid materials are discharged therefrom in the Z-axis direction. Note that electrothermal transducers may be provided instead of piezo elements. Specifically, the head 114 may have a configuration in which the liquid material 111 is discharged by use of the thermal expansion of the material due to the electrothermal transducers.

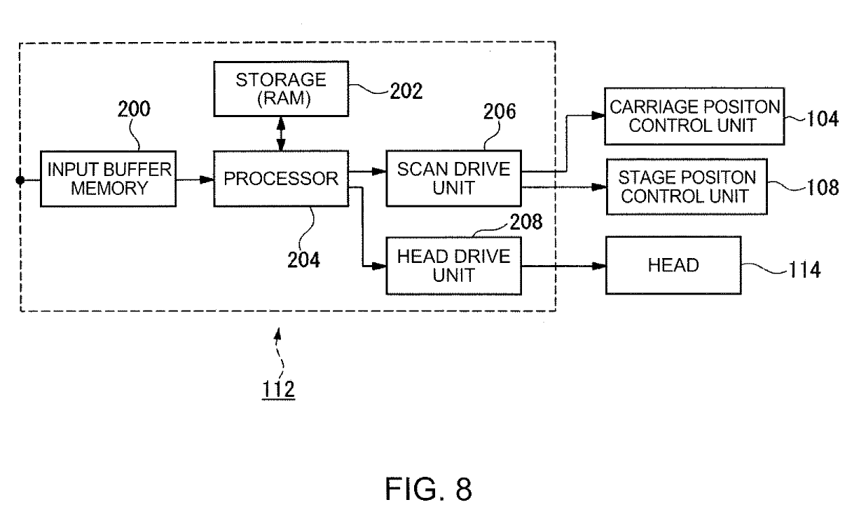

The configuration of the controller 112 will be described below based on FIG. 8.

The controller 112 is a unit for overall control of the operation of the discharge device 100: the timing of discharging the liquid material 111, the fixation position of the carriage 103, the movement (the movement velocity, movement distance and so on) of the stage 106, and so forth.

As shown in FIG. 8, the controller 112 includes an input buffer memory 200, a storage 202, a processor 204, a scan drive unit 206, and a head drive unit 208. These components are coupled to each other so that they can communicate with each other.

The input buffer memory 200 receives, from an externally coupled e.g. information processing device, discharge data for discharging droplets of the liquid materials 111. The input buffer memory 200 supplies the discharge data to the processor 204, and the processor 204 stores the discharge data in the storage 202. As the storage 202, e.g. RAM is used.

The processor 204 accesses the discharge data stored in the storage 202, and supplies requisite drive signals to the scan drive unit 206 and the head drive unit 208 based on the discharge data.

Based on the drive signal, the scan drive unit 206 supplies a certain position control signal to the carriage position control unit 104 and the stage position control unit 108. In addition, based on the drive signal, the head drive unit 208 supplies to each head 114 a discharge signal for discharging the liquid material 111.

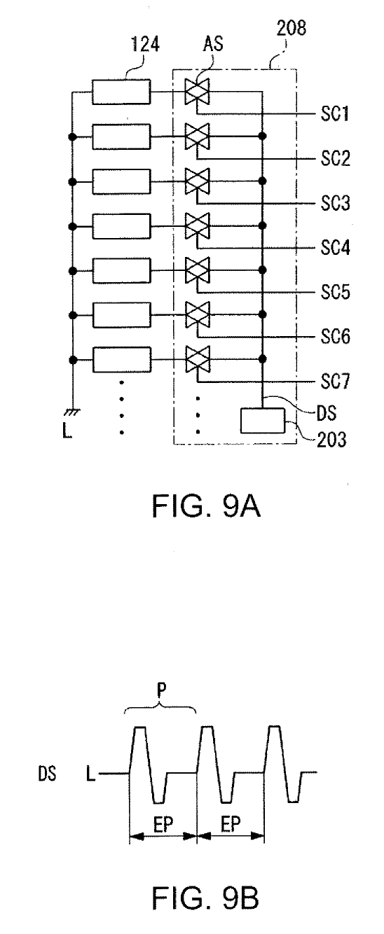

Referring to FIG. 9A, the head drive unit 208 has one drive signal generator 203 and a plurality of analog switches AS. The analog switches AS are coupled to the oscillators 124 in the heads 114. Specifically, the analog switches AS are coupled to the electrodes 124A although the electrodes 124A are not illustrated in FIG. 9A. Each analog switch AS is provided corresponding to a respective one of the nozzles 118, and therefore the number of the analog switches AS is the same as the number of the nozzles 118.

The drive signal generator 203 generates a drive signal DS like one shown in FIG. 9B. The drive signal DS is supplied to the input terminal of each analog switch AS independently. The potential of the drive signal DS changes relative to a reference potential L with time. Specifically, the drive signal DS is a signal in which a discharge waveform P is repeated with a discharge cycle EP. The discharge cycle EP is adjusted to a desired value by the processor 204 for example.

The drive signal generator 203 can output the drive signal DS only to a certain analog switch AS, and can drive only the nozzle 118 to discharge the liquid material 111. Furthermore, the discharge cycle EP can be adjusted adequately, and thus discharge signals can be generated so that the plural nozzles 118 discharge the liquid material 111 in a certain nozzle order.

Method of Manufacturing Liquid Crystal Device (Droplet Discharge Method)

Manufacturing steps for the liquid crystal device 1 with the above-described configuration will be described below.

As an example, the present embodiment employs a method in which a plurality of liquid crystal devices are collectively formed by use of large-area mother substrates, and then the mother substrates are separated into the individual liquid crystal devices 1 by cutting.

Initially, a simple description will be made about a formation step for a color-filter mother substrate.

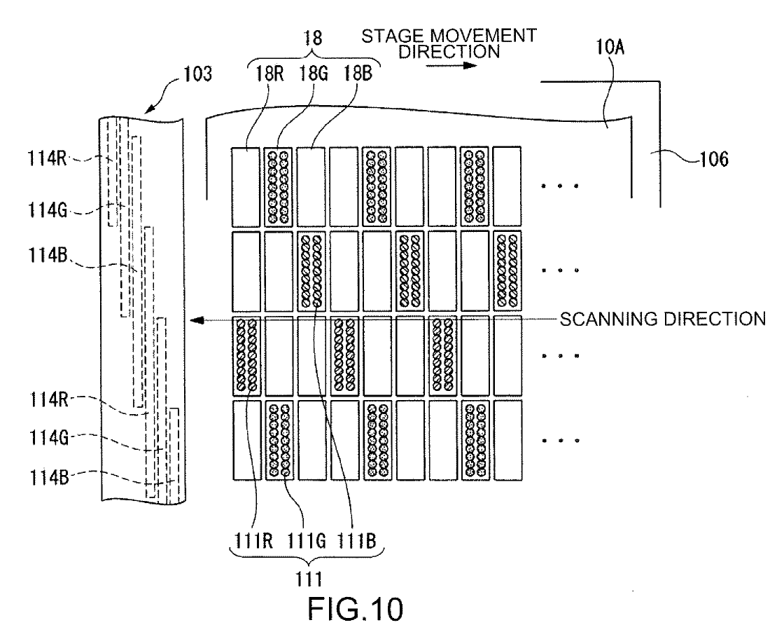

The base 10A is placed on the stage 106 of the discharge device 100 so as to be held by the stage 106. Formed on the base 10A are parts 18 (18R, 18G, 18B, see FIG. 10 and so on) on which liquid materials are to be discharged, and that hold thereon layers of the respective colors of the color filters 16 (hereinafter, referred to as discharged material receivers 18). The discharged material receivers 18R hold thereon the red layers 16R. The discharged material receivers 18G hold thereon the green layers 16G. The discharged material receivers 18B hold thereon the blue layers 16B. When the base 10A is placed on the stage 106 so as to be held by the stage 106, the position of the base 10A is adjusted so that the direction parallel to the short sides of the base 10A corresponds with the X-axis direction and the direction parallel to the long sides thereof corresponds with the Y-axis direction.

In this state, as shown in FIG. 10, the stage 106 is moved from the left to the right in the drawing. Thus, the carriage 103 scans the base 10A from the right to the left in the drawing, for example. While the carriage 103 scans the base 10A, the liquid material 111 is discharged from each head 114.

In one scanning of the carriage 103, if the discharge nozzles 118 of a certain head 114 (the nozzles between the reference nozzles 118R near the both ends of the head 114) do not cover one discharged material receiver 18 across the entire length of the discharged material receiver 18 in the direction perpendicular to the scanning direction, the liquid material 111 is not discharged on the discharged material receiver 18. That is, if the discharge nozzles 118 of the certain head 114 cover the whole of one discharged material receiver 18, the head 114 discharges the liquid material 111 on the discharged material receiver 18. In contrast, if the discharge nozzles 118 of the certain head 114 do not cover the whole of one discharged material receiver 18, the head 114 does not discharge the liquid material 111 on the discharged material receiver 18.

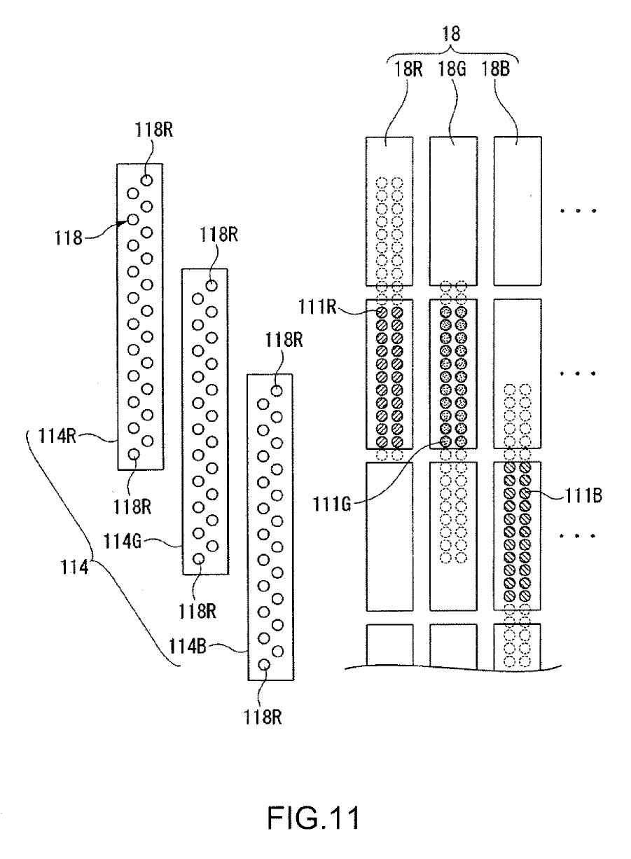

A more specific description will be made based on FIG. 11. FIG. 11 is a diagram schematically showing the discharging of the liquid material 111 from each head 114. In FIG. 11, the reference nozzles 118R are located at the ends of each head 114, for facilitation of understanding.

Referring to FIG. 11, when attention is paid on the head 114R for example, the following relationships between the discharge nozzles 118 (including the reference nozzles 118R) of the head 114R and the discharged material receivers 118 are apparent. Specifically, the discharge nozzles 118 cover part of the uppermost discharged material receiver 18R in the drawing, and cover the whole of the discharged material receiver 18R on the second row from the top in the drawing. In contrast, no discharge nozzle 118 covers the discharged material receiver 18R on the third row from the top in the drawing. In this case, the liquid material 111 (the red material 111R) is discharged only on the discharged material receiver 18R of which entire region is covered by the nozzles 118, i.e., only on the discharged material receiver 18R on the second row from the top in the drawing.

As for the head 114G, the discharge nozzles 118 of the head 114G cover part of the uppermost discharged material receiver 18G, and cover the whole of the discharged material receiver 18G on the second row, and cover part of the discharged material receiver 18G on the third row. In this case, the liquid material 111 (the green material 111G) is discharged only on the discharged material receiver 18G of which entire region is covered by the nozzles 118, i.e., only on the discharged material receiver 18G on the second row from the top in the drawing.

As for the head 114B, the discharge nozzles 118 of the head 114B do not cover the uppermost discharged material receiver 18B, and cover part of the discharged material receiver 18B on the second row, and cover the whole of the discharged material receiver 18B on the third row. In this case, the liquid material 111 (the blue material 111B) is discharged only on the discharged material receiver 18B of which entire region is covered by the nozzles 118, i.e., only on the discharged material receiver 18B on the third row from the top in the drawing.

When the materials are discharged in such a method, as shown in FIG. 10, the green material 111G is discharged on the discharged material receivers 18 on the uppermost row in the drawing, and the blue material is discharged on the discharged material receivers 18 on the second row from the top in the drawing. In addition, the red material 111R is discharged on the discharged material receivers 18 on the third row from the top in the drawing, and the green material 111 is discharged on the discharged material receivers 18 on the lowermost row in the drawing.

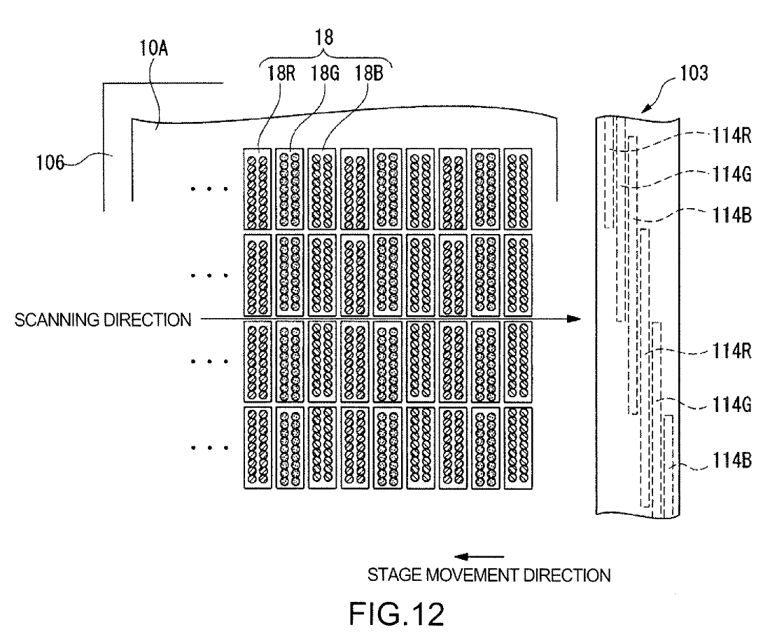

Before each of the subsequent scanning steps, the position of the carriage 103 is controlled so that the nozzles 118 of the intended liquid material 111 cover the whole of the discharged material receivers 18 on which the liquid material 111 has not been discharged yet. The discharging with the scanning of the carriage 103 is repeated until the liquid materials 111 have been discharged on all the discharged material receivers 18 as shown in FIG. 12.

The subsequent steps will be simply described below. On the base 10A on which the color filters 16 have been formed, electrodes and interconnects (not shown) are formed, and a planarization film is formed thereon. In addition, formed on the surface of the base 10A are spacers and partition walls (not shown) for gap control. Subsequently, an alignment layer is formed to cover the interconnects and color filters formed on the base 10A, and then rubbing-treatment is implemented for the alignment layer. The alignment layer can be formed by applying or printing polyimide for example. Furthermore, a sealing material composed of epoxy resin or the like is formed into a rectangular ring, and a liquid crystal is applied on the region surrounded by the sealing material.

Subsequently, an active-matrix mother substrate is formed as follows. Interconnects, electrodes and other components are formed on a large-size substrate composed of an optically transparent material such as glass or plastic. A planarization film is then formed on the region in which the interconnects, electrodes and so on have been formed. After the formation of the planarization film, an alignment layer composed of polyimide or the like is formed, and rubbing-treatment is carried out for the alignment layer.

Subsequently, the color-filter mother substrate and the active-matrix mother substrate are applied to each other into a panel form. Specifically, the both substrates are brought close to each other, and the active-matrix mother substrate is bonded to the sealing material on the color-filter mother substrate. Thereafter, scribe lines are formed on the both bonded mother substrates, and the panel is cut along the scribe lines. Each of the divided panels is cleaned, and a driver and so on are formed on each of the panels. A polarizer is applied to the outer surface of each liquid crystal panel, and the backlight 41 is attached to the panel. Thus, the liquid crystal device 1 is completed.

As described above, according to the present embodiment, the positions that readily cause streak unevenness in the respective heads 114, i.e., the positions in the X-axis direction of the reference nozzles 118R in the heads 114 are offset relative to each other on each head basis. Therefore, when the liquid materials 111 are discharged while the carriage 103 scans the base 10A, the positions of streak unevenness in the liquid material 111 discharged from the respective heads 114 do not overlap with each other, which can prevent the streak unevenness of the liquid material from being noticeable across the entire substrate.

When the heads 114 are offset relative to each other as described above, a situation possibly arises where, in one scanning, the entire lengths of some discharged material receivers 18 in the direction perpendicular to the scanning direction (hereinafter, the perpendicular direction) are covered by the nozzles 118, while only part of the lengths of other discharged material receivers 18 in the perpendicular direction are covered by the nozzles 118. Therefore, it is needed to repeat the discharging of the liquid material 111 with the carriage 103 being moved in the perpendicular direction before each discharging. However, in such discharging operation, the liquid material 111 is discharged in one discharged material receiver 18 twice or more with time intervals, which possibly causes unevenness in the discharged liquid material 111.

In contrast, according to the present embodiment, only when the entire length of the discharged material receiver 18 in the perpendicular direction is covered by the nozzles 18, the liquid material 111 is discharged to the discharged material receiver 18 from the nozzles 118, which overlap with the discharged material receiver 118 horizontally. Therefore, when only part of the discharged material receiver 18 is covered for example, the liquid material 111 is not discharged, which prevents the occurrence of unevenness in the discharged liquid material 111. Thus, unevenness of the liquid material 111 can be made obscure across the entire substrate.

Electronic Apparatus

An electronic apparatus to which one embodiment of the invention is applied will be described below by taking a cellular phone as an example.

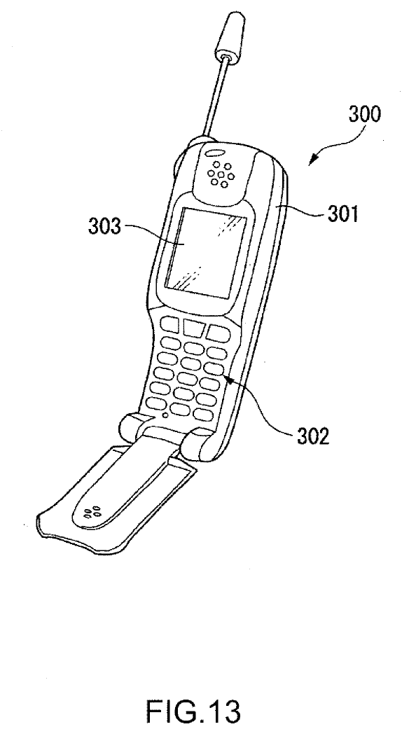

FIG. 13 is a perspective view illustrating the entire configuration of a cellular phone 300.

The cellular phone 300 includes a casing 301, an operation part 302 including a plurality of operation buttons, and a display part 303 that displays pictures, moving images, characters and so on. The display part 303 incorporates the liquid crystal device 1 according to one embodiment of the invention.

Since the high-quality liquid crystal device 1 allowing uniform displaying is incorporated, an electronic apparatus (the cellular phone 300) having an excellent display performance can be achieved.

It should be noted that the technical scope of the invention is not limited to the above-described embodiment, but modifications may be adequately incorporated in the embodiment without departing from the scope and spirit of the invention.

In addition, the invention is not limited to the above-described example, in which one embodiment of the invention is applied to the formation of the color filter layers 16 on the color filter substrate 3 of the liquid crystal device 1. For example, embodiments of the invention can also be applied to the formation of organic layers (luminescent layers or the like) on an organic EL device substrate.

What is claimed is:

1. A droplet discharge method comprising
discharging a droplet of a functional liquid on a discharged material receiver provided on a substrate from a plurality of nozzles in a plurality of discharge heads while the plurality of discharge heads relatively scan the substrate, wherein
the size of a discharge area formed of the plurality of nozzles in a first direction perpendicular to a second direction in which the plurality of discharge heads relatively scan the substrate is larger than the size of the discharged material receiver in the first direction, and
if the whole of the discharged material receiver is covered by the discharge area, a droplet of the functional liquid is discharged from the plurality of nozzles to the discharged material receiver, and if at least part of the discharged material receiver is not covered by the discharge area, a droplet of the functional liquid is not discharged from the plurality of nozzles to the discharged material receiver.

2. The droplet discharge method according to claim 1, wherein
in the discharging, the plurality of discharge heads relatively scan the substrate in a state where the positions in the first direction of nozzles at both ends in the first direction of the plurality of nozzles in the plurality of discharge heads are offset relative to each other on each discharge head basis.

3. An electro optical device comprising a substrate on which a functional liquid is discharged by the droplet discharge method according to claim 1.

4. An electronic apparatus comprising the electro optical device according to claim 3.
